(19) United States
(12) Patent Application Publication
(10) Pub. No.: US 2008/0157324 A1
(43) Pub. Date: Jul. 3, 2008

(54) Stacked die package with die interconnects

(76) Inventors: Jia Miao Tang, Shanghai (CN); Xiang Yin Zeng, Shanghai (CN); Dao Qiang Lu, Chandler, AZ (US); Jiang Qi He, Gilbert, AZ (US)

Correspondence Address: INTEL/BLAKELY, 1279 OAKMEAD PARKWAY, SUNNYVALE, CA, 94085-4040, US

(21) Appl. No.: 11/648,420

(22) Filed: Dec. 28, 2006

(51) Int. Cl. H01L 23/02; H01L 21/00

(52) U.S. Cl. 257/686; 438/109; 257/E21.001; 257/E23.18

(57) ABSTRACT

A method of forming a package, comprising providing a set of dies on a substrate. The dies may be stacked on the substrate and may be coupled to the substrate by an interconnect provided on a side surface of the stacked dies.

### BACKGROUND

Stacked die packages may require wire bonds having increased lengths to accommodate the stacked dies. During fabrication, movement of bonding wires such as wire sweep may result in a short circuit between adjacent bonding wires. In addition, spacers are often required among the stacked dies to create the necessary space for the wire bonds. Some stacked die packages comprise dies of different sizes, specifically to create enough space for the wire bonds and eliminate the need for a spacer.

### BRIEF DESCRIPTION OF THE DRAWINGS

The invention described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements.

FIG. 1A-1E are schematic diagrams of an embodiment of a method that may form a package;

FIG. 2A and 2B are schematic diagrams of an embodiment of another method that may form a package;

FIG. 3 is a schematic diagram of an embodiment of a memory system.

### DETAILED DESCRIPTION

In the following detailed description, references is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein, in connection with one embodiment, may be implemented within other embodiments without departing from the spirit and scope of the invention.

In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numbers refer to the same or similar functionality throughout the several views.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described.

The following description may include terms, such as upper, lower, top, bottom, first, second, etc. that are used for descriptive purposes only and are not to be construed as limiting.

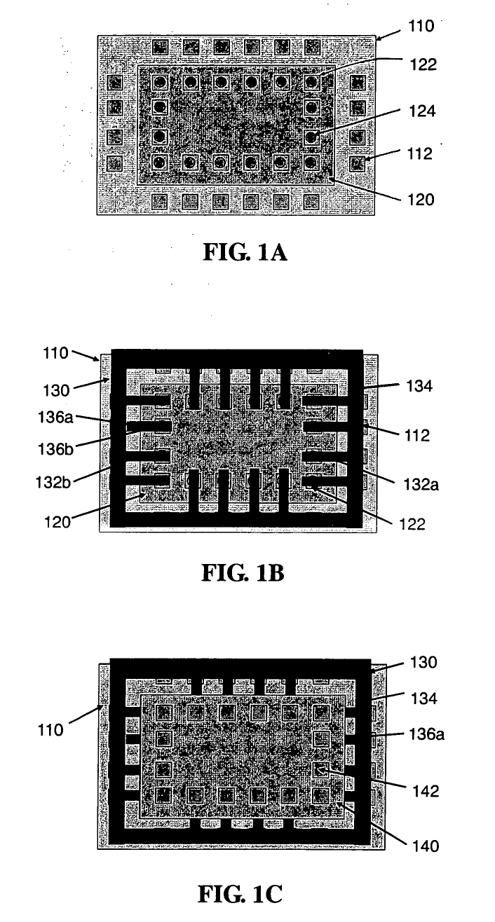

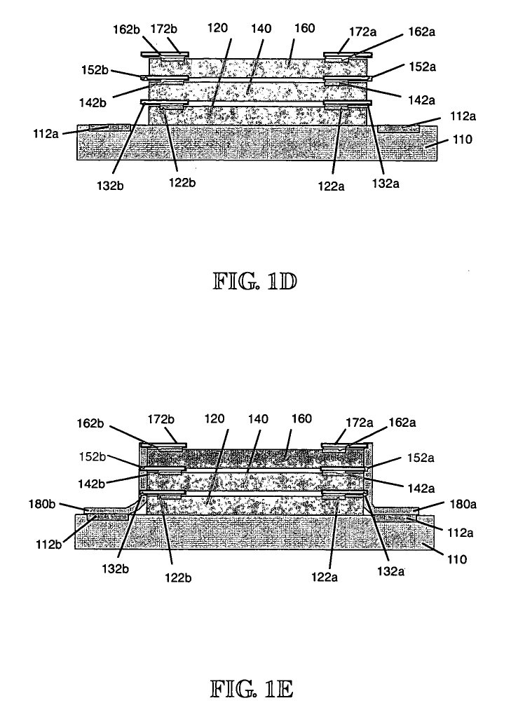

FIGS. 1A-1E illustrate an example embodiment of a method of forming a package with one or more stacked dies. As shown in FIG. 1A, in one embodiment, a first die 120 may be stacked onto a substrate 110. For example, the first die 120 may be mounted to one side, e.g., a top surface, of the substrate 110. In one embodiment, an adhesive (not shown) may be used to attach the first die 120 to the substrate 110. For example, the adhesive may comprise epoxy resin, or any other die attach adhesive. In another embodiment, an adhesive film may be used for attaching the first die 120 on the substrate 110. One example of the substrate 110 may comprise a printed circuit board (PCB) or a printed wiring board (PWB); however, any other suitable substrate may be utilized, including flex substrates such as folded flex substrates or flexible polyimide tape, laminate substrates such as bismaleimide triazine (BT) substrates, buildup substrates, ceramic substrates, flame retardant (FR-4) substrate, or tape automated bonding (TAB) tape material.

Referring to FIG. 1A, the substrate 110 may comprise one or more pads 112 on one side, e.g., the top side as shown in FIG. 1A. In one embodiment, any suitable conductive materials may be utilized, including one or more metals. Although FIG. 1A illustrates the embodiment that may use pads 112, the substrate 110 may be configured with bond pads, bond fingers, bond areas, traces, routings, pins, I/O terminals or any other types of interconnects. As shown in FIG. 1A, the one or more pads 112 may be arranged along edges or periphery of the substrate 110; however, in some embodiments, the pads 112 may be provided on the substrate 110 where no die is to be disposed.

Referring again to FIG. 1A, in one embodiment, the first die 120 may comprise one or more pads 122; however, other embodiments may comprise bond pads, bond fingers, bond areas, traces, routings, I/O terminals, pins, or any other types of interconnects. In one embodiment, the die 120 may be configured with the pads 122 to interconnect the first die 120 with the substrate 110. For example, the one or more pads 122 may be arranged along edges or periphery of the first die 120. In another embodiment the pads 122 may be arranged on top of the first die 120, however, in some embodiment, the first die 120 may comprise one or more pads on the back side. As shown in FIG. 1A, conductive paste or adhesive 124 may be dispensed on top of each pad 122. In one embodiment, the conductive paste 124 may comprise one or more of copper (e.g., copper paste, nano-copper paste), silver, tin, or any other conductive adhesive or composite.

Referring now to FIG. 1B, a first lead frame 130 may be disposed on the first die 120. In one embodiment, the first lead frame 130 may support one or more leads, such as leads 132a and 132b. For example, the first lead frame 130 may comprise a frame portion 134 and one or more leads, e.g., 132a and 132b that may be joined together by the frame portion 134 at a first end 136a of each lead. In another embodiment, each lead may be configured to match a pad 122 on the first die 120. For example, the first lead frame 130 may be coupled to the first die 120 by the leads, e.g., 132a and 132b that may each be bonded to a pad 122 at a second end 136b of each lead. In another embodiment, the one or more leads of the first lead frame 130 may each be coupled to a pad 122 by the conductive paste 124 on the pad 122.

While FIG. 1B illustrates to use leads, in some embodiments, other interconnects may be utilized. For example, a pad 122 may be extended or configured to protrude over an edge or side surface of the first die 120. In another embodiment, a pad 122 may extend from an upper surface of the first die 120 to an edge or side surface of the first die 120. In yet another embodiment, conductive material such as conductive paste or conductive film may be applied on a pad 122, wherein the conductive material may protrude over an edge or extend to a side surface of the first die 120. Further, while FIG. 1B illustrates to utilize a lead frame, in some embodiments, a conductive frame or a metal frame that comprises one or more conductive interconnects may be utilized.

The first lead frame 130 or at least the leads thereof may be made from, e.g., any suitable conductive materials or metals, such as copper, or other metals. In another embodiment, the conductive paste 124 on each pad 122 may be cured, so that each lead may be electrically and/or mechanically connected to a pad 122 by the conductive paste 124. In another embodiment, the conductive paste 124 may fix each lead to a pad 122. In another embodiment, each lead of the first lead frame 130 may be coupled to a corresponding pad 112 on the substrate 110. As shown in FIG. 1B, in one embodiment, the first end 136a of each lead may protrude over an edge or side surface of the first die 120. In another embodiment, the frame portion 134 may surround the first die 120. In yet another embodiment, the frame portion 134 may not overlap with the first die 120.

Referring now to FIG. 1C, in one embodiment, a second die 140 may be stacked onto the first die 120 with the first lead frame 130 provided between the two dies. In one embodiment, a die similar to the first die 120 of FIG. 1A may be utilized for the second die 140. For example, the second die 140 may be disposed on the first lead frame 130 and may contact the one or more leads of the first lead frame 130. In one embodiment, an adhesive (not shown) may be used to attach the second die 140 to the first lead frame 130 and/or the first die 120. In one embodiment, the adhesive may comprise epoxy resin, or any other die attach adhesive, or the die attach adhesive of FIG. 1A. Examples of the second die 140 may refer to the embodiments as described above with reference to the first die 120. In one embodiment, the second die 140 may have the same size and/or shape as the first die 120; however, in some embodiment, the size of the second die 140 may not be the same as the first die 120.

Referring to FIG. 1C, in one embodiment, the second die 140 may be positioned above the first die 120. In another embodiment, the first and second dies 120 and 140 may be overlapped with each other, as seen from top of the second die 140. Referring to FIG. 1C, in one embodiment, the first end 136a of each lead on the first lead frame 130 may protrude over an edge or side surface of the second die 140. In another embodiment, the frame portion 134 may not contact the second die 140. In another embodiment, each pad 142 may be arranged on the second die 140 in the same manner as that of the first die 120. In yet another embodiment, each pad 142 may match a pad 122 on the first die 120. For example, each pad 142 may be aligned with a pad 122, e.g., in a vertical direction of FIG. 1D.

In one embodiment, a stack of a set of dies and/or a set of lead frames may be provided on the substrate 110 in the same manner as described with regard to FIGS. 1A-1C. In another embodiment, the set of dies and the set of lead frames may be interleaved. FIG. 1D is a side view that illustrates three stacked dies on the substrate 110. In one embodiment, a third die 160 may be stacked on the second die 140. The three dies 120, 140 and 160 may be interleaved with three lead frames. For example, the first lead frame 130 of FIG. 1 B may be disposed on the first die 120; a second lead frame may be disposed on the second die 140; and a third lead frame may be provided on the third die 160, and so on. In one embodiment, the first lead frame 130 that comprises a lead portion 134 and a set of leads, e.g., 132a and 132b may be utilized for the three lead frames. Each lead frame may be removed. Any suitable way may be used to remove each lead frame. For example, the frame portion of each lead frame may be cut away, or each lead frame may be trimmed to retain the leads.

In another embodiment, each lead may match a pad of a corresponding die. Referring to FIG. 1D, each lead provided on the first die 120 may be coupled to a pad on the first die 120. For example, leads 132a and 132b provided on the first die 120 may be coupled to corresponding pads 122a and 122b, respectively. Similarly, in another embodiment, each lead provided on the second die 140 may be coupled to a pad on the second die 140, and each lead provided on the third die 160 may be coupled to a pad on the third die 160. For example, leads 152a and 152b provided on the second die 140 may be coupled to pads 142a and 142b, respectively, and leads 172a and 172b provided on the third die 160 may be coupled to pads 162a and 162b, respectively. Referring to FIG. 1D, in another embodiment, the leads of each lead frame may protrude over the periphery of any die. For example, leads 132a, 132b, 152a, 152b, 172a and 172 may each protrude over an edge or side surface of each dies 120, 140 or 160.

FIG. 1E is a side view that illustrates to utilize an die interconnect to couple the dies 120,140 and 160 and/or the substrate 110. In one embodiment, the die interconnect may extends from an upper die to a lower die. In another embodiment, the die interconnect may further extend to the substrate 110. Referring to FIG. 1E, in one embodiment, the leads on each die may be aligned in a vertical direction. For example, leads 132a, 152a and 172a may be aligned in a queue, line or column in the vertical direction. In another embodiment, leads 132b, 152b and 172b may be aligned in the vertical direction to form another queue or column. In another embodiment, each column of aligned leads may be mated with a pad on the substrate 110. For example, the column of leads 132a, 152a and 172a may correspond to a pad 112a on the substrate 110. In another embodiment, the column of leads 132b, 152b and 172b may be mated with a pad 112b on the substrate 110.

Referring to FIG. 1E, in one embodiment, an die interconnect may be formed on a side surface of the dies 120, 140 and 160 to couple the dies. In another embodiment, the die interconnects may be further coupled to the substrate 110. For example, the die interconnect 180a may be connected to a set of leads 132a, 152a, and 172a and/or a pad 112a on the substrate 110. In another embodiment, the die interconnect 180b may be coupled to another column of leads 132b, 152b and 172b and/or a pad 112b on the substrate 110. In one embodiment, any suitable conductive paste or adhesive may be utilized to form the die interconnect. For example, conductive paste or adhesive 180a may be dispensed, e.g., by a dispenser (not shown) on an edge or side surface of the stack of dies 120, 140 and 160 to contact the lead 132a, 152a and 172a at a portion of each lead that protrudes over the side surface of the stack of dies. Similarly, conductive paste or adhesive 180b may be applied to another side surface of the dies 120, 140 and 160 to couple to a corresponding set of leads 132b, 152b and 172b and/or the pad 112b. In another embodiment, the conductive paste or adhesive, e.g., 180a or 180b may be cured or hardened.

Referring to FIG. 1E, in one embodiment, the conductive paste or adhesive 180a and/or 180b may comprise copper, silver, or tin, or any other suitable conductive materials. In another embodiment, the conductive paste 180a and 180b may utilize the same material as that of the conductive paste 124. While FIG. 1E illustrates the conductive paste 180a and 180b, in some embodiments, each set of aligned leads may be coupled to a pad on the substrate 110 by respective die interconnect. For example, one set of aligned leads and a corresponding pad 112 may be isolated or insulated from another set of aligned leads and another corresponding pad 112.

While FIGS. 1D and 1E illustrate three stacked dies, in some embodiments, a different number dies of may be stacked, and a lead frame may be provided on each die. In another embodiment, the dies and/or the lead frames may not have the same size. FIGS. 1D and 1E shows that the pads on one die may be aligned with the pads on another die and the leads on one die may be aligned with the leads on another die; however, in some embodiments, the alignment may not be required. For example, a lead on each of the die 120, 140, 160 may be coupled together with a pad on the substrate 110 by conductive paste or adhesive that may be provided to the protruded portions of the set of leads and pad. The set of leads and pad may be insulated from another set of leads and pad. While FIGS. 1d and 1E illustrate to use an die interconnect couple the dies and/or the substrate 110, in some embodiments, an uppermost die 160 may be coupled to a lower die 140 by bumps.

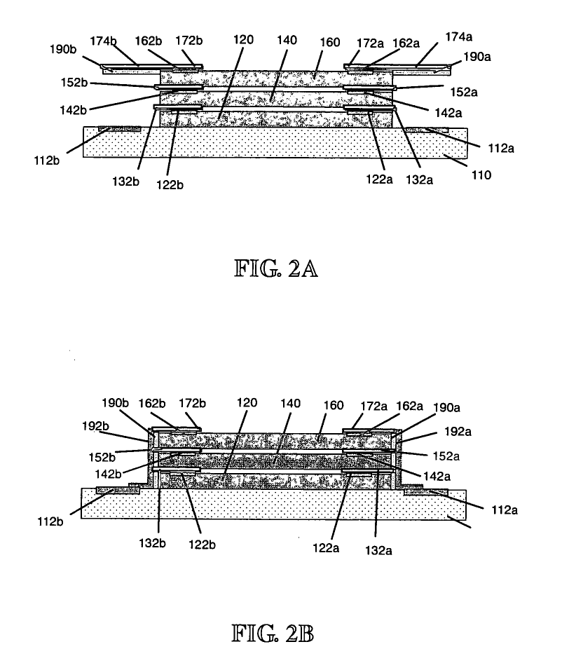

Referring to FIGS. 2A and 2B, an embodiment of a method that may utilize conductive adhesive or film is illustrated. In one embodiment, the example of FIG. 2A is similar to that of FIG. 1D except that a conductive film or adhesive may be attached to a lower side of each lead on an upper die at a protruded portion of the lead. For example, referring to FIG. 2A, a conductive film or adhesive 190a may be provided on a lower side of the lead 172a on the upper or top die 160. In another embodiment, the lead 172 may comprise a protruded portion 174a, a lower side of which may be provided with the conductive film 190a. For example, the protruded portion 174a may protrude over an edge of any dies 120, 140 and 160 to an increased length compared to the lower protruded portion 132a or 152a. In another embodiment, a conductive film or adhesive 190b may be disposed on a lower side of a protruded portion 174b of the lead 172b on the upper die 160.

In one embodiment, the protruded portion 174b may have an increased length compared to the lower protruded portion 132b or 152b. In one embodiment, the length of the protruded portion 174a may be the same as that of the protruded portion 174b; however, in some embodiments, they may be different. In another embodiment, the length of each protruded portion may be equal to the length of each conductive film attached to the portion; however, in some embodiments, it may not be required. In yet another embodiment, any suitable conductive material may be utilized for a conductive film or adhesive, including copper, silver, tin or any other conductive adhesive. The conductive film or adhesive may be attachable to a lower side of the leads. In another embodiment, conductive paste may be utilized.

Referring to FIG. 2B, the conductive film 190a may be folded to contact two leads 132a and 152a that may be aligned with the lead 172a in a vertical direction, e.g., at the protruded portions of the two leads. In another embodiment, the conductive film 190a may further contact the pad 112a that may be mated with the set of aligned leads 132a, 152a, and 172a; however, in some embodiments, this may not be required. In yet another embodiment, the conductive film 190a may couple the leads 132a, 152a and 172a to the pad 112a. In yet another embodiment, the conductive film 190a may be attached to a side surface or edge of each die 120, 140 or 160 and/or the protruded portions of leads 132a, 152a and 172a.

Similarly, referring to FIG. 2B, the conductive film 190b may be folded to contact lead 152b and/or lead 132b that may be provided on two lower dies 140 and 120, respectively. In one embodiment, the conductive film 190b may be coupled to the protruded portions of the leads 132b and 152b. In another embodiment, the leads 132b, 152b and 172b may be coupled together by the conductive film 190b. In yet another embodiment, the protruded portion 174b may be trimmed to comprise a reduced length that protrudes over the edge or side surface of the die 160; however, in some embodiments, the length of the protruded portion 174b may be unchanged.

The conductive film 190b may further reach the pad 112b; however, this may not be required. For example, leads 132b, 152b and 172b may be coupled to the pad 112b by conductive adhesive or paste 192b that may be provided on the conductive film 190b and/or the lead 172b. In one embodiment, the conductive adhesive or paste 192b may be cured. In another embodiment, the conductive adhesive or paste 192b may comprise conductive material the same as any conductive paste as described above; however, different conductive material may be used.

In one embodiment, an encapsulant or molding compound (not shown) may be provided to encapsulate the structure of FIG. 1E or FIG. 2E. In another embodiment, the encapsulant or molding compound may not be required. Examples of the package may comprise flash memory, static random access memory (SDRAM), digital signal processor (DSP), application specific integrated circuit (ASIC), logic circuits, CPU, system level components, or any other circuits or devices. In another embodiment, the substrate 110 may be provided with external interconnects for the package, such as ball grid array or land grid array.

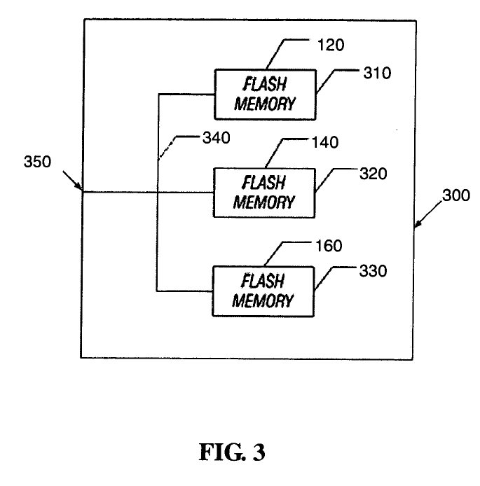

In one embodiment, the package of FIG. 1E or FIG. 2E may be used to provide a memory system. FIG. 3 illustrates an embodiment of a memory system 300 that may be formed in one package. In one embodiment, a universal serial bus (USB) flash memory or any other memory may be formed in one package. The memory system 30 may comprise three flash memories 310, 320 and 330 that may be coupled to I/O terminal 350. In one embodiment, the flash memory 330 may be implemented by the third die 160, the flash memory 320 may be implemented by the second die 140, the flash memory 310 may be implemented by the first die 120.

One or more interconnects 340 may couple the flash memories 310, 320 and 330 and the I/O terminal 350. The interconnects 340 may be made up of the substrate 110, and/or one or more of the interconnects from a group comprising 112, 122, 132a, 132b, 142a, 142b, 152a, 152b, 162a, 162b, 172a, 172b, 180a, 180b, 190a, 190b, 192a, 192b, or external interconnects (not shown). In one embodiment, the memory system 300 may be coupled to an external I/O 350 via the substrate 110 and/or external interconnects (not shown) on the substrate 110. Although the embodiment of FIG. 3 is illustrated to use three flash memories, in some embodiments, other memory devices may be utilized, such as NOR, NAND, dynamic random access memory (DRAM). Again, in some embodiments, a different number of memory devices may be utilized. In one embodiment, the memory system 300 may further comprise a control (not shown) that may be implemented as one or more dies on the substrate 110. For example, the control may comprise a memory controller, a digital signal processor (DSP), a processor, logic circuit or any other control unit or device. For example, the control may be coupled to each of the memory devices 310, 320 and 330. In another embodiment, the control may be coupled to the external I/O terminal 350 via the substrate 110.

While the methods of FIGS. 1A-1E and FIGS. 2A and 2B are illustrated to comprise a sequence of processes, the method in some embodiments may perform illustrated processes in a different order. Further, while the embodiments of FIGS. 1A-1E and FIGS. 2A and 2B are illustrates to comprise a certain number of dies, pads, lead frames, leads, interconnects, conductive films and substrates, some embodiments may apply to a different number. While FIG. 1E utilizes an die interconnect to couple each die to a substrate, in some embodiments, conductive paste or adhesive may be provided that may extend from an upper surface of an upper die to an edge of the upper die to form an die interconnect. The die interconnect may be connected to a lead on a lower die and/or a corresponding pad on the substrate to coupled the upper die to the lower die and/or the substrate.

While certain features of the invention have been described with reference to embodiments, the description is not intended to be construed in a limiting sense. Various modifications of the embodiments, as well as other embodiments of the invention, which are apparent to persons skilled in the art to which the invention pertains are deemed to lie within the spirit and scope of the invention.

What is claimed is:

1. A method, comprising:
providing a substrate having a lower die, and
providing an die interconnect that extends on a side surface of the lower die to couple the lower die to the substrate.

2. The method of claim 1, comprising:
providing on the lower die a lower interconnect that protrudes over the side surface of the lower die to couple to the die interconnect.

3. The method of claim 1, wherein the die interconnect extends to an interconnect on the substrate.

4. The method of claim 1, wherein the die interconnect extends to a side surface of an upper die provided on the lower die to couple to the upper die.

5. The method of claim 4, comprising:
providing on the upper die an upper lead, wherein the upper lead protrudes over the side surface of the upper die to couple to the die interconnect.

6. The method of claim 1, comprising:
providing on the lower die a lower lead coupled to the lower die, wherein one end of the lower lead protrudes over the side surface of the lower die to couple to the die interconnect.

7. The method of claim 6, comprising removing a lead frame that supports the lower lead.

8. The method of claim 1, comprising:
providing conductive paste on the side surface of the lower die to provide the die interconnect.

9. The method of claim 1, comprising:
providing an upper die on the lower die,
providing a conductive adhesive on an upper interconnect, wherein one end of the conductive adhesive protrudes over a side surface of the upper die; and
folding the end of the conductive adhesive to provide the die interconnect.

10. The method of claim 9, comprising:
providing on the lower die a lower lead, wherein the lower lead protrudes over the side surface of the lower die to couple to the die interconnect.

11. A package, comprising:
a substrate having a lower die;
a die interconnect attached to a side surface of the lower die, wherein the die interconnect is coupled to the lower die.

12. The package of claim 11, further comprising:
a lower interconnect provided on the lower die, wherein the lower interconnect protrudes over the side surface of the lower die to couple to the die interconnect.

13. The package of claim 11, further comprising:
an upper die on the lower die, wherein the die interconnect extends to a side surface of the upper die, and
an upper interconnect provided on the upper die, wherein the upper interconnect protrudes over the side surface of the upper die to couple to the die interconnect.

14. The package of claim 11, wherein the die interconnect is coupled to the substrate.

15. The package of claim 13, wherein the lower die and the upper have the same size.

16. The package of claim 11, further comprising:
a lead provided on the lower die, wherein one end of the lead protrudes over the side surface of the lower die to couple to the die interconnect.

17. The package of claim 11, wherein the die interconnect comprises one of a group of conductive paste, a conductive film and a conductive adhesive.

18. A memory system, comprising:
a substrate,
a set of memory devices stacked on the substrate, and
a die interconnect provided on a side surface of the memory devices to couple the memory devices to the substrate.

19. The memory system of claim 18, comprising:
an interconnect provided on each memory device, wherein one end of each interconnect couples to a memory device and the other end of each interconnect protrudes over the side surface to couple to the die interconnect.

20. The memory system of claim 18, comprising:
at least three leads each coupled to one of the memory devices, wherein the die interconnect couples the substrate to a protruded portion of each lead that protrudes over the side surface of one of the memory devices.

21. The memory system of claim 18, wherein the memory devices comprise a set of dies that have the same size.

22. The memory system of claim 18, comprising:
a control provided on the substrate, wherein the control comprise a die that is coupled to the die interconnect.
